(19) United States
(12) Patent Application Publication
(10) Pub. No.: US 2015/0076529 A1
(43) Pub. Date: Mar. 19, 2015

(54) LIGHT-EMITTING DEVICE

(71) Applicant: KABUSHIKI KAISHA TOSHIBA, Tokyo (JP)

(72) Inventors: Ping WANG, Kanagawa (JP); Nozomu TAKAHASHI, Kanagawa (JP)

(73) Assignee: KABUSHIKI KAISHA TOSHIBA, Tokyo (JP)

(21) Appl. No.: 14/191,250

(22) Filed: Feb. 26, 2014

(30) Foreign Application Priority Data
Sep. 13, 2013 (JP) 2013-191190

(51) Int. Cl. H01L 25/075; H01L 33/00; H01L 33/54; H01L 33/62; H01L 33/50; H01L 33/58; H01L 33/60

(52) U.S. Cl. CPC H01L 25/0753; H01L 33/58; H01L 33/0075; H01L 33/60; H01L 33/62; H01L 33/0079; H01L 33/505; H01L 33/507; H01L 33/54; H01L 2933/0041; H01L 2933/005; H01L 2933/0058; H01L 2933/0066
USPC 257/88; 438/27

(57) ABSTRACT

A light-emitting device includes a resin layer and a plurality of luminous bodies disposed on the resin layer and spaced from each other. Each luminous body has a first side contacting the resin layer and a second side opposite the first side. A wiring element connects the luminous bodies to each other with the wiring element contacting the luminous bodies on the first side. At least some portion of the wiring element is in the resin layer. Separate phosphor layers are disposed on the second side of each luminous body such that each phosphor layer is spaced from each other phosphor layer.

### CROSS-REFERENCE TO RELATED APPLICATION

This application is based upon and claims the benefit of priority from Japanese Patent Application No. 2013-191190, filed Sep. 13, 2013, the entire contents of which are incorporated herein by reference.

### FIELD

Embodiments described herein relate generally to light-emitting devices.

### BACKGROUND

The development of light-emitting devices using a luminous body such as a light emitting diode (LED) and a phosphor in combination has been advancing. Modularizing a plurality of luminous bodies within these light-emitting devices is potentially effective for increasing the light output and also making these light-emitting devices more efficient. By integrating a plurality of luminous bodies at the wafer level and configuring the luminous bodies as a one-chip module, miniaturization may be implemented with reduce costs. However, when the plurality of luminous bodies is integrated at the chip level, the light extraction efficiency is sometimes reduced by mutual interference between phosphor layers arranged on the luminous bodies.

### DESCRIPTION OF THE DRAWINGS

FIGS. 1A to 1C are schematic diagrams depicting a light-emitting device according to an embodiment.

FIGS. 2A to 2C are schematic sectional views depicting production processes of the light-emitting device according to the embodiment.

FIGS. 3A to 3C are schematic sectional views depicting additional production processes of the light-emitting device according to the embodiment continued from FIGS. 2A to 2C.

FIGS. 4A to 4C are schematic sectional views depicting additional production processes of the light-emitting device according to the embodiment continued from FIGS. 3A to 3C.

FIGS. 5A to 5C are schematic sectional views, each depicting a light-emitting device according to a modified example of the embodiment.

FIGS. 6A and 6B are schematic sectional views, each depicting a light-emitting device according to another modified example of the embodiment.

FIG. 7 is a schematic sectional view depicting a light-emitting device according to a comparative example.

### DETAILED DESCRIPTION

A light-emitting device with reduced mutual interference between phosphor layers arranged on a plurality of luminous bodies within the light-emitting device is described as an example embodiment of the present disclosure.

In general, according to one embodiment, a light-emitting device includes a resin layer and a plurality of luminous bodies disposed on the resin layer. The luminous bodies are disposed so as to be spaced from each other in a direction generally parallel to the resin layer plane. The luminous bodies each have a first side with a first surface that is contacting the resin layer and a second side, which is opposite the first side, with a second surface. A wiring (wiring element) electrically connects the luminous bodies to each other. For example, the luminous bodies may be wired in series with each other or in parallel with each other. The wiring contacts the luminous bodies on the first side. At least some portion of the wiring is in the resin layer. For example, a vertical (generally perpendicular to the resin layer plane) portion of the wiring can be within the resin layer and a horizontal (generally parallel to the resin layer plane) portion of the wiring can be on a back-side surface of the resin layer. A phosphor layer is disposed on the second surface of each luminous body and each phosphor layer is spaced from each other phosphor layer that may be adjacent.

Hereinafter, embodiments will be described with reference to the drawings. Identical portions in the drawings are identified with common reference numerals and the detailed descriptions thereof may be omitted as appropriate, and only different portions may be described in discussing the various figures. Incidentally, the drawings are schematic or conceptual diagrams, and the relationship between the thickness and the width of each portion, the size ratio between one portion and the other portion, and the like are not necessarily identical to the relationship, the size ratio, and the like of an actual device. Moreover, even when the same portion is depicted, the dimensions and ratio thereof may be different in different drawings.

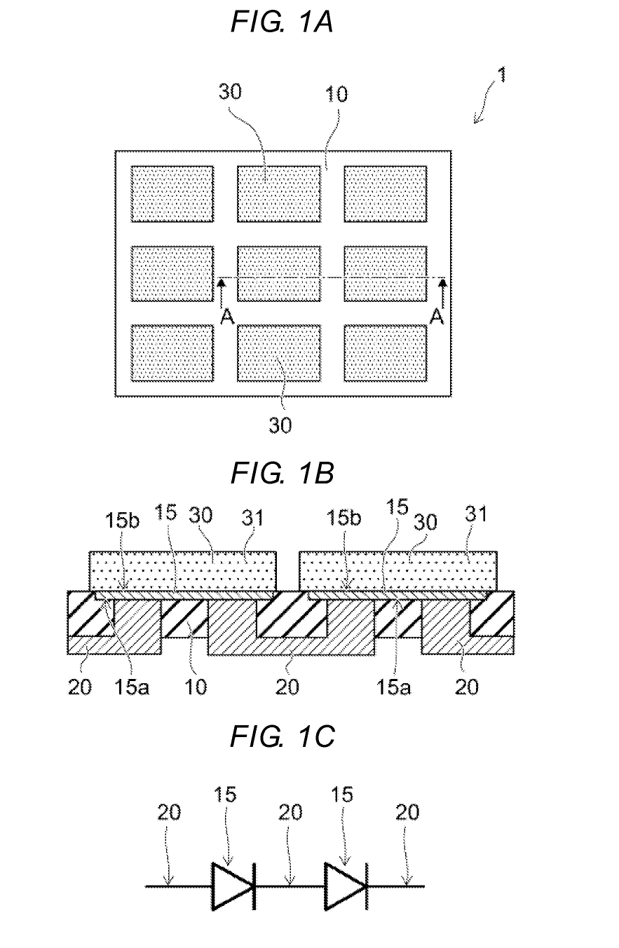

FIGS. 1A to 1C are schematic diagrams depicting a light-emitting device 1 according to an embodiment. FIG. 1A is a top view depicting a light-emitting face side of the light-emitting device 1. FIG. 1B is a sectional view taken on the line A-A depicted in FIG. 1A. FIG. 1C is a schematic diagram depicting a circuit configuration of the light-emitting device 1.

The light-emitting device 1 includes a resin layer 10, a plurality of luminous bodies 15 arranged on the resin layer 10, wiring 20 that electrically connect the adjacent luminous bodies 15, and phosphor layers 30 provided on the luminous bodies 15.

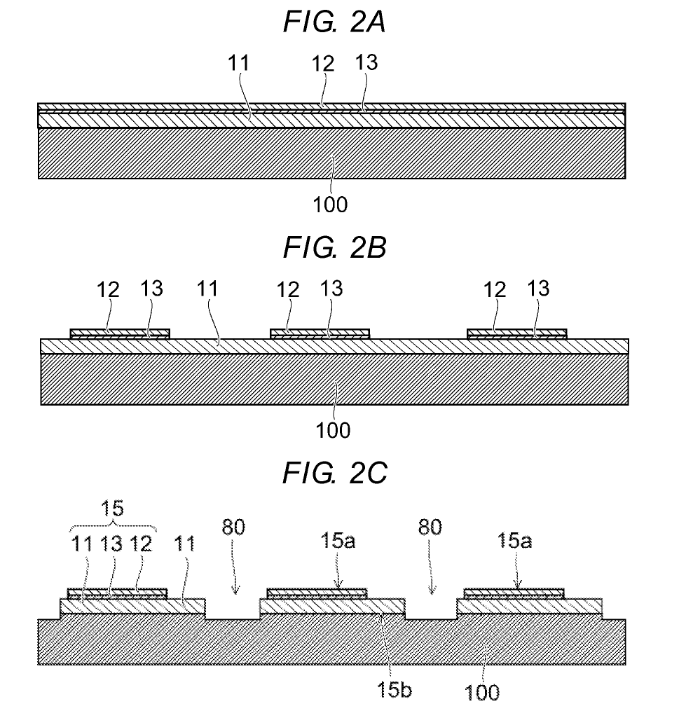

Each luminous body 15 is, for example, an LED and has a first face 15a on the side where the luminous body 15 is in contact with the resin layer 10 and a second face 15b on aside opposite to the first face 15a. The luminous body 15 may be a laminated body including, for example, an n-type semiconductor layer (first semiconductor layer) 11, a p-type semiconductor layer (second semiconductor layer) 12, and an emission layer (light-emitting layer) 13 provided between the n-type semiconductor layer 11 and the p-type semiconductor layer 12 (see FIGS. 2A to 2C).

As depicted in FIG. 1B, each wiring 20 electrically connects the adjacent two luminous bodies 15 on the side of the luminous body 15 where the first face 15a is located—that is, each wiring 20 connects to the luminous bodies 15 at the first face 15a. The luminous bodies 15 may be connected in series with each other via the wiring 20 as depicted in FIG. 1C or may be connected in parallel with each other.

At least part of each wiring 20 is provided in the resin layer 10. In an example depicted in FIG. 1B, a portion of the wiring 20, the portion that is connected to the luminous body 15, is provided in the resin layer 10, and a another portion of the wiring 20, the portion extending between the adjacent luminous bodies 15, is provided on a face (hereinafter, a rear face) of the resin layer 10 on the side opposite to a face of the resin layer 10 that is in contact with the luminous body 15. As depicted in FIG. 1B, the vertical (up-down page direction) portions of wiring 20 are within the resin layer 10 and the horizontal (left-right page direction) portions of wiring 20 are outside the resin layer 10 on a surface of resin layer 10. The disclosure is not limited to this example arrangement, and, for example, the whole of the wiring 20 may be provided in the resin layer 10 instead of just a portion.

On the side of the luminous body 15 where the second face 15b is located, the phosphor layer 30 is provided. The phosphor layer 30 contains, for example, a phosphor 31 that is excited by a light emitted from the luminous body 15 and emits a light with a wavelength which is different from the wavelength of the light emitted from the luminous body 15. That is, the phosphor layer 30 has a wavelength conversion function in that it absorbs light emitted by luminous body 15 at a first wavelength and then emits light at a different, second wavelength. In another embodiment, a structure in which a transparent resin layer, whose principal ingredient is silicone resin or the like, is provided on the second face 15b in place of the phosphor layer 30 to directly extract the light emitted from the luminous body 15 may also be adopted.

The phosphor layer 30 is provided on each of the luminous bodies 15. In addition, the phosphor layers 30 are disposed separated from one another on the resin layer 10. For example, as depicted in FIG. 1A, the phosphor layers 30 may be disposed in a matrix with a spacing or gap between adjacent phosphor layers 30.

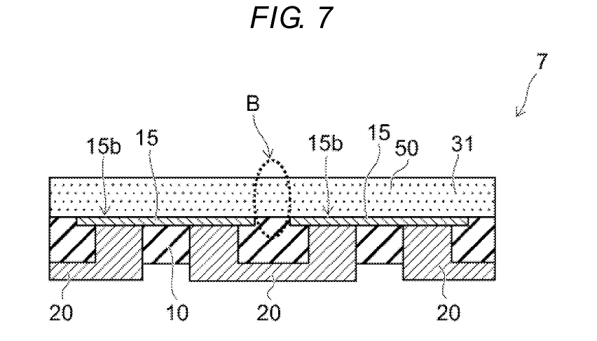

FIG. 7 is a schematic sectional view depicting a light-emitting device 7 according to a comparative example. The light-emitting device 7 includes a resin layer 10, a plurality of luminous bodies 15 arranged on the resin layer 10, wiring 20 that electrically connect the adjacent luminous bodies 15, and a phosphor layer 50 provided on the luminous bodies 15. As depicted in FIG. 7, the phosphor layer 50 is provided on the resin layer 10 in a continuous manner in such a way as to cover the second faces 15b of the luminous bodies 15.

In the light-emitting device 7, a drive current is supplied to the luminous bodies 15 via the wiring 20 to make the luminous bodies 15 emit light. The light emitted from the luminous bodies 15 passes through the phosphor layer 50 and is released to the outside. In the course of this process, the phosphor 31 contained in the phosphor layer 50 absorbs part of the emitted light of the luminous bodies 15 and emits a light with a wavelength which is different from the wavelength of the light emitted from the luminous bodies 15. As a result, the light-emitting device 7 may output a mixed light of the emitted light of the luminous bodies 15 and the emitted light of the phosphor 31. In addition, by appropriately selecting the type of the phosphor 31, lights of various colors may be output from the light-emitting device 7.

On the other hand, the process of wavelength conversion in the phosphor 31 involves a loss of light energy. For example, as depicted in FIG. 7, when the phosphor layer 50 is formed in a continuous manner, the optical path length of a light that propagates in the phosphor layer 50 in a transverse direction (not perpendicular to the face 15b) increases and the light is attenuated accordingly. Furthermore, in a region B of the phosphor layer 50 between the adjacent luminous bodies 15, the intensity of the excited light is reduced by attenuation. As a result, the energy loss caused by the absorption by the phosphor 31 becomes relatively greater, resulting in a reduction in efficiency of light extraction from the phosphor layer 50.

On the other hand, the phosphor layers 30 are provided on the luminous bodies 15 in such a way that the phosphor layers 30 are separated from one another. As a result, the potential optical path length of a light that propagates in the phosphor layer 30 in a transverse direction may be shortened as the phosphor layer 30 does not extend between luminous bodies 15. Furthermore, since the phosphor 31 is not present in a portion in which the luminous body 15 is not arranged, the energy loss caused by the absorption by the phosphor 31 may be reduced. As a result, in the light-emitting device 1, the efficiency of light extraction from the phosphor layer 30 may be improved.

Next, with reference to FIGS. 2A to 4C, a method for producing light-emitting device 1 will be described. FIGS. 2A to 4C are schematic sectional views depicting an example of a production process of the light-emitting device 1 according to the embodiment.

FIG. 2A is a sectional view depicting an n-type semiconductor layer 11, a p-type semiconductor layer 12, and an emission layer 13 which are formed on a principal surface of a substrate 100. For example, by using metal organic chemical vapor deposition (MOCVD), the n-type semiconductor layer 11, the emission layer 13, and the p-type semiconductor layer 12 are grown, sequentially, on the substrate 100. The substrate is, for example, a silicon substrate. The n-type semiconductor layer 11, the emission layer 13, and the p-type semiconductor layer are, for example, nitride semiconductors and can contain gallium nitride (GaN).

Next, as depicted in FIG. 2B, for example, by using reactive ion etching (RIE), the p-type semiconductor layer 12 and the emission layer 13 are selectively etched, whereby the n-type semiconductor layer 11 is exposed. Patterning is performed on the p-type semiconductor layer 12 and the emission layer 13 so that portions of the p-type semiconductor layer 12 and the emission layer 13 are left like islands on the n-type semiconductor layer 11. These island-like portions are used to form a plurality of light-emitting regions on the substrate 100.

Then, as depicted in FIG. 2C, the n-type semiconductor layer 11 is selectively removed such that the exposed portions of n-type layer 11 that are between the island-like portions of p-type semiconductor 12 and emission layer 13 are removed, whereby a plurality of luminous bodies 15 are formed on the substrate 100.

For example, an etching mask (not shown) that covers the p-type semiconductor layer 12 and the emission layer 13 is provided on the n-type semiconductor layer 11. Then, by using RIE, the n-type semiconductor layer 11 is etched, whereby grooves 80 reaching the substrate 100 are formed. As a result, for example, as depicted in FIG. 1A, the plurality of luminous bodies 15 disposed in matrix may be formed on the substrate 100. Each luminous body 15 is a laminated body including the n-type semiconductor layer 11, the p-type semiconductor layer 12, and the emission layer 13 provided between the n-type semiconductor layer 11 and the p-type semiconductor layer 12.

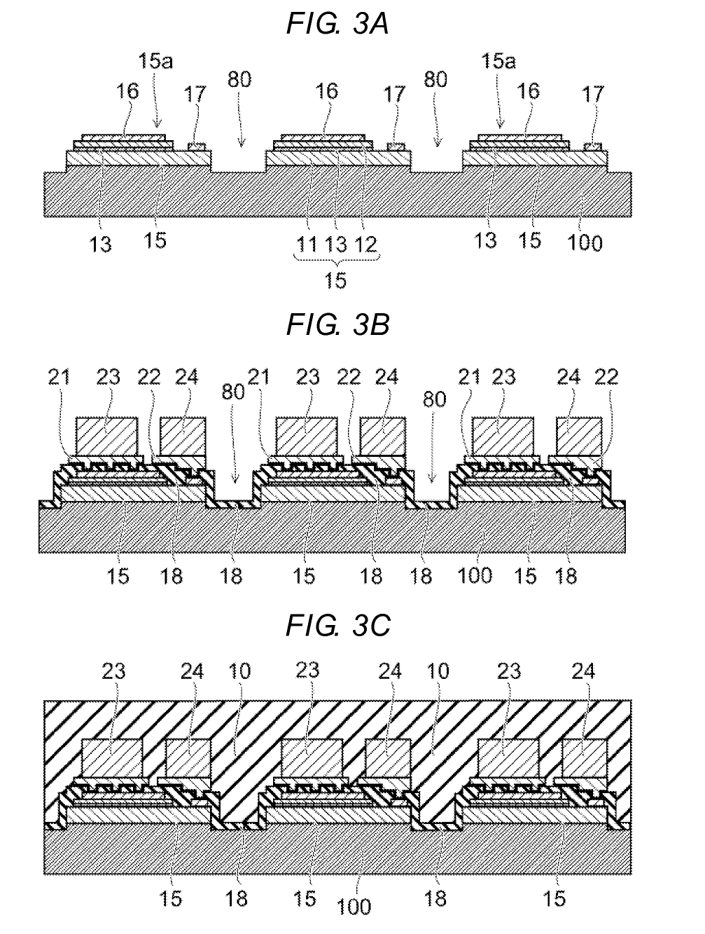

Next, as depicted in FIG. 3A, on the side of the luminous body 15 where a second face 15a is located, a p-electrode 16 and an n-electrode 17 are formed. The p-electrode 16 is formed on the p-type semiconductor layer 12. The n-electrode 17 is formed on the n-type semiconductor layer 11.

The p-electrode 16 and the n-electrode 17 are formed using, for example, sputtering or evaporative deposition. The p-electrode 16 may be formed before the n-electrode 17 and vice versa. The p-electrode 16 and the n-electrode 17 may also be formed of the same material and at the same time. Preferably, the p-electrode 16 is formed in such a way as to reflect a light emitted from the emission layer 13, for example. The p-electrode 16 may contain, for example, silver, a silver alloy, aluminum, or an aluminum alloy. Moreover, to prevent sulfuration and oxidation of the p-electrode 16, a structure including a metal protection film (a barrier metal film) may also be adopted.

Next, as depicted in FIG. 3B, an insulating film 18 that covers the luminous bodies 15 and the substrate 100 is formed. In the insulating film 18, a first opening communicating with the p-electrode 16 and a second opening communicating with the n-electrode 17 are formed—that is, insulating film 18 has a hole/opening through which a connection to the p-electrode 16 can be made and another hole/opening through which a connection to then-electrode 17 can be made. The insulating film 18 is, for example, a silicon oxide film or a silicon nitride film and may be formed using chemical vapor deposition (CVD).

Then, on the insulating film 18, a p-side wiring layer 21 and an n-side wiring layer 22 are formed. The p-side wiring layer 21 is electrically connected to the p-electrode 16 via the first opening provided in the insulating film 18. Moreover, the n-side wiring layer 22 is electrically connected to the n-electrode 17 via the second opening provided in the insulating film 18. Furthermore, a p-side pillar (contact) 23 is formed on the p-side wiring layer 21, and an n-side pillar (contact) 24 is formed on the n-side wiring layer 22. The p-side wiring layer 21, the n-side wiring layer 22, the p-side pillar 23, and the n-side pillar 24 are, for example, metal whose principal ingredient is copper formed using electrolytic plating.

The p-side wiring layer 21 and the n-side wiring layer 22 determine the area ratio between the p-electrode 16 and the n-electrode 17 to form the pillars.

For example, to increase the light output of the luminous body 15, the area of the emission layer 13 can be increased. Therefore, the area of the p-type semiconductor layer 12 formed on the emission layer 13 can be larger than an exposed portion of the n-type semiconductor layer 11 in which the n-electrode 17 is provided. To make the current injected into the emission layer 13 more nearly uniform, the p-electrode 16 can be formed in such a way as to cover the entire surface of the p-type semiconductor layer 12. As a result, the p-electrode 16 is wider than the n-electrode 17.

On the other hand, to form a wiring connected to the p-electrode 16 and the n-electrode 17, preferably, the area ratio between the p-electrode 16 and the n-electrode 17 is close to 1. Thus, by providing the p-side wiring layer 21 and the n-side wiring layer 22, the area ratio between the p-electrode 16 and the n-electrode 17 is optimized. As a result, the p-side pillar 23 and the n-side pillar 24 which are part of the wiring 20 are formed easily.

Next, as depicted in FIG. 3C, a resin layer 10 that covers the p-side wiring layers 21, the n-side wiring layers 22, the p-side pillars 23, the n-side pillars 24, the luminous bodies 15, and the insulating film 18 is formed.

The resin layer 10 contains carbon black, for example, and blocks the emitted light of the luminous bodies 15. Moreover, the resin layer 10 may contain, for example, a component, such as titanium oxide, which reflects the emitted light of the luminous bodies 15.

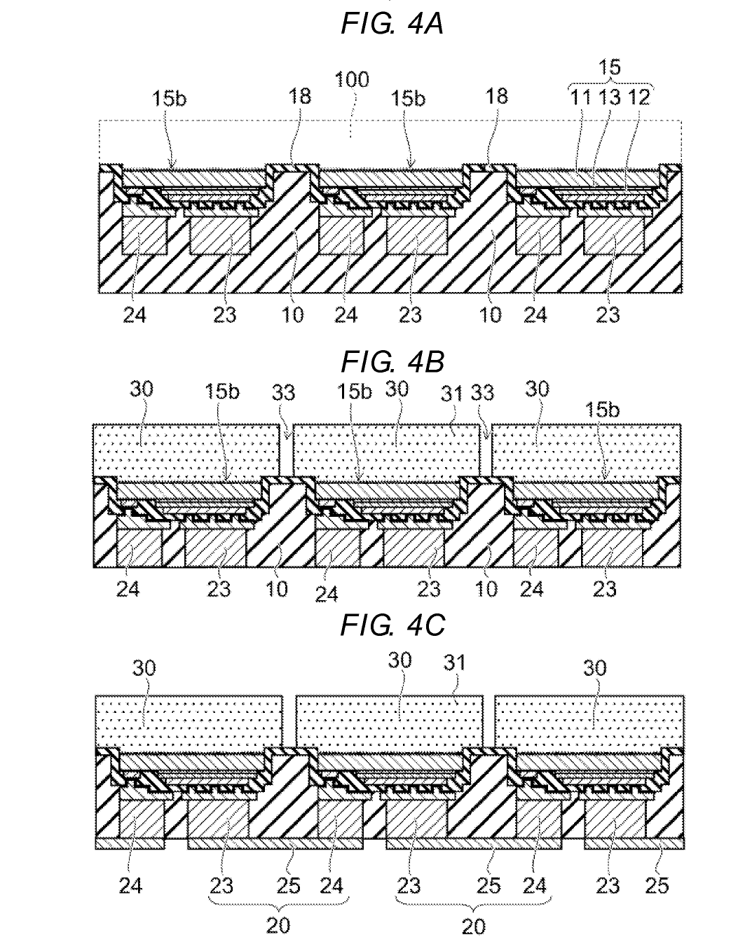

Next, processing is performed on the sides of the luminous bodies 15 where second faces 15b are located. FIGS. 4A to 4C are sectional views obtained by turning FIG. 3C upside down.

As depicted in FIG. 4A, the substrate 100 is removed from the luminous bodies 15. For example, when a silicon substrate is used as the substrate 100, the substrate 100 may be selectively removed by wet etching. Preferably, minute projections and depressions (sometimes referred to as concave-convex structures or a frosting process) are formed on the surfaces (the second faces 15b) of the luminous bodies 15 from which the substrate 100 is removed. By doing so, the efficiency of light extraction from the luminous bodies 15 to the phosphor layer 30 may be improved by reducing interfacial reflections.

Next, as depicted in FIG. 4B, on the second faces 15b of the luminous bodies 15, phosphor layers 30 are formed. The phosphor layer 30 is formed, for example, as a continuous layer on the luminous bodies 15 and the resin layer 10. Then, grooves 33 are formed between the adjacent luminous bodies 15 to obtain a plurality of phosphor layers 30 separated from one another. The grooves 33 are formed in such away as to communicate with the insulating film 18. Thus, for example, the grooves 33 may extend from an upper surface (as depicted in FIG. 4B) of phosphor layers 30 to an upper surface of insulating film 18.

Next, a rear face side of the resin layer 10 is ground (or otherwise processed) to expose the end faces of the p-side pillars 23 and the n-side pillars 24.

Then, as depicted in FIG. 4C, on a rear face of the resin layer 10, wiring 25, each electrically connecting the p-side pillar 23 and the n-side pillar 24 of the adjacent luminous bodies 15, are formed. That is, each wiring 20 that electrically connects the adjacent luminous bodies 15 includes, for example, the p-side pillar 23, the n-side pillar 24, and the wiring 25.

Then, between the adjacent luminous bodies 15, the insulating film 18 and the resin layer 10 are cut to obtain individual light-emitting devices 1, each as depicted in FIGS. 1A to 1C.

The light-emitting device 1 produced by the processes described above is a one-chip module inside which the plurality of luminous bodies 15 are encapsulated in resin and includes the wiring that electrically connect the plurality of luminous bodies 15. The light-emitting device 1 with such a structure may implement significant miniaturization and reduction in cost.

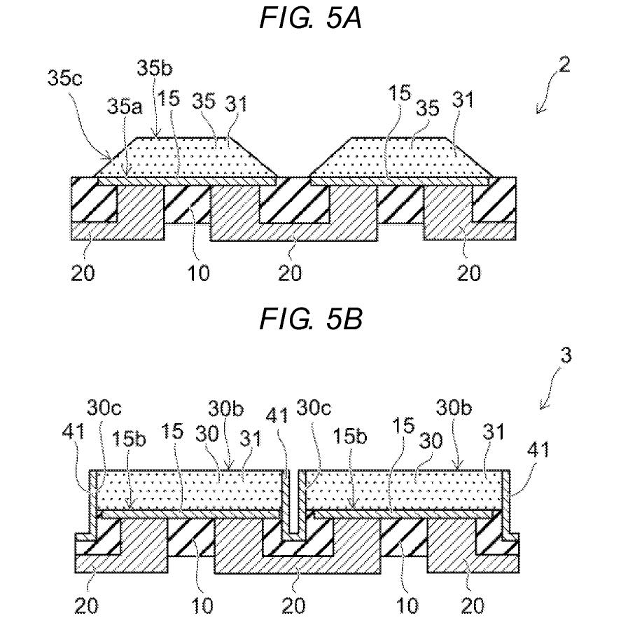

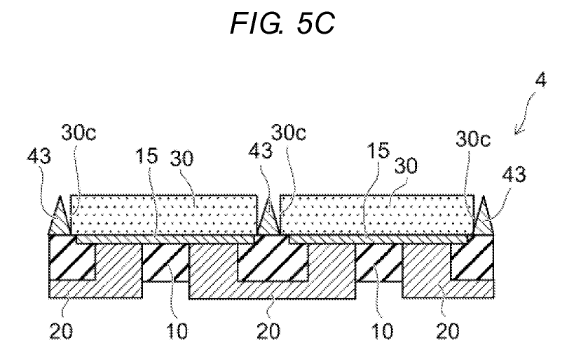

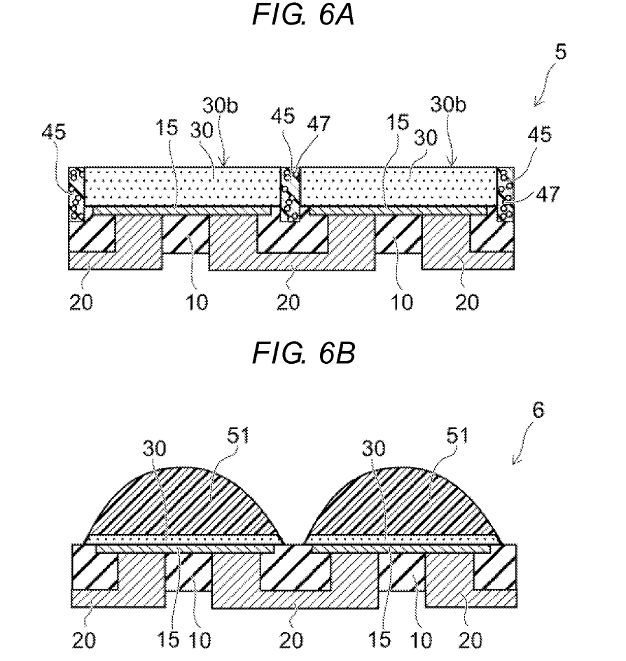

Next, with reference to FIGS. 5A to 5C and FIGS. 6A and 6B, light-emitting devices according to modified examples of the embodiment will be described. FIGS. 5A to 6B are schematic sectional views depicting light-emitting devices 2 to 6 according to the modified examples of the embodiment.

FIG. 5A is a sectional view depicting the light-emitting device 2. The light-emitting device 2 includes a resin layer 10, a plurality of luminous bodies arranged on the resin layer 10, wiring 20 that electrically connect the adjacent luminous bodies 15, and phosphor layers 35 provided on the luminous bodies 15. Each phosphor layer 35 contains a phosphor 31.

The phosphor layer 35 has a shape in which a face (a top face 35b) on a side opposite to the luminous body 15 is narrower than a face in contact with the luminous body 15. That is, the phosphor layer 35 has inwardly inclined side faces 35c.

For example, in the phosphor layer obtained by division into the size of the luminous body 15, the light emitted not only from the top face thereof but also from the side face thereof is Lambertian (directionally diffuse) and contributes to light output. In this example, by processing the end of the phosphor layer 35 into a tapered shape, the light distribution angle of the light emitted from the side faces 35c is shifted upward. As a result, absorption by another phosphor layer 35 adjacent to the phosphor layer 35 is suppressed and the light extraction efficiency may be improved.

FIG. 5B is a sectional view depicting the light-emitting device 3. The light-emitting device 3 includes a resin layer 10, a plurality of luminous bodies arranged on the resin layer 10, wiring 20 that electrically connects the adjacent luminous bodies 15, and phosphor layers 30 provided on the luminous bodies 15. Each phosphor layer 30 contains a phosphor 31.

Furthermore, the phosphor layer 30 has side faces 30c intersecting a face which is parallel to the second face 15b of the luminous body 15 and reflectors 41 provided on the side faces 30c. Each reflector 41 reflects the light emitted from the luminous body 15 and the emitted light of the phosphor 31.

In the light-emitting device 3, the light from the side faces 30c of the phosphor layer 30 is reflected by the reflectors 41 and is extracted upward. Each reflector is, for example, a dielectric multilayer film. Moreover, as the reflector 41, for example, metal having a high reflectivity, such as aluminum or silver, may be used. The light that propagates toward the side faces 30c of the phosphor layer 30 is reflected upward by the reflectors 41 and is released from a top face 30b of the phosphor layer 30. As a result, the luminous efficiency of the light-emitting device 3 may be improved.

FIG. 5C is a sectional view depicting the light-emitting device 4. The light-emitting device 4 includes a resin layer 10, a plurality of luminous bodies arranged on the resin layer 10, wiring 20 that electrically connect the adjacent luminous bodies 15, and phosphor layers 30 provided on the luminous bodies 15. Each phosphor layer 30 contains a phosphor 31.

Furthermore, between the phosphor layers 30 provided on the adjacent two luminous bodies 15, a reflector 43 that reflects the emitted lights of the two luminous bodies 15 is provided. The reflector 43 extends in such a way as to surround each of the plurality of phosphor layers 30.

The reflector 43 is formed using, for example, metal having a high reflectivity, such as aluminum or silver, or a multilayer dielectric film. Preferably, the reflector 43 is formed into a tapered shape so that the reflector 43 reflects upward the light released from the phosphor layer 30. As a result, absorption by another phosphor layer 30 adjacent to the phosphor layer 30 is suppressed and the light extraction efficiency may be improved.

FIG. 6A is a sectional view depicting the light-emitting device 5. The light-emitting device 5 includes a resin layer 10, a plurality of luminous bodies arranged on the resin layer 10, wiring 20 that electrically connects the adjacent luminous bodies 15, and phosphor layers 30 provided on the luminous bodies 15. Each phosphor layer 30 contains a phosphor 31.

Furthermore, the light-emitting device 5 includes a resin body 45 that is provided between the phosphor layers 30 provided on the adjacent two luminous bodies 15. The resin body 45 contains a scattering material 47 that scatters the emitted lights of the two luminous bodies 15 and the emitted light of the phosphor 31.

For example, the inside of the groove 33 dividing the phosphor layer 30 is filled with the resin body 45. The scattering material 47 is, for example, silica particles and scatters the emitted lights of the luminous body 15 and the phosphor 31 in multiple directions. As a result, the percentage of the light released from a top face 30b of the phosphor layer 30 is increased, whereby the luminous efficiency may be improved.

FIG. 6B is a sectional view depicting the light-emitting device 6. The light-emitting device 6 includes a resin layer 10, a plurality of luminous bodies arranged on the resin layer 10, wiring 20 that electrically connects the adjacent luminous bodies 15, and phosphor layers 30 provided on the luminous bodies 15. Each phosphor layer 30 contains a phosphor 31.

Furthermore, the light-emitting device 6 includes a lens 51 provided on each of the plurality of phosphor layers 30. The lens 51 is formed by, for example, molding a transparent resin such as silicone on the phosphor layer 30. By collecting the emitted lights of the luminous body 15 and the phosphor 31 with the lens, absorption by the adjacent phosphor layer 30 is reduced and the light extraction efficiency may be improved.

As described above, in the embodiment, between the phosphor layers provided on the luminous bodies 15, a gap, a reflector, or the like is disposed. As a result, absorption of the emitted light of the luminous body 15 by the adjacent phosphor layer is suppressed and the light extraction efficiency of the light-emitting device including the plurality of luminous bodies 15 may be improved. Moreover, the lens 51 used in the light-emitting device 6 may be formed on the phosphor layers of the light-emitting devices 2 to 5.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light-emitting device comprising:
a resin layer;
a plurality of luminous bodies disposed on the resin layer to be spaced from each other, the luminous bodies each having a first side with a first surface that is contacting the resin layer and a second side opposite the first side with a second surface;
a wiring that electrically connects the luminous bodies to each other, the wiring contacting the luminous bodies on the first side, at least a first portion of the wiring being in the resin layer; and
a plurality of phosphor layers that are disposed on the second surface of each luminous body, each phosphor layer being spaced from each other phosphor layer.

2. The light-emitting device according to claim 1, wherein each phosphor layer has a tapered shape such that a planar area of an upper face of the phosphor layer is less than a planar area of a lower face that is in contact with the luminous body.

3. The light-emitting device according to claim 2, wherein each phosphor layer has a trapezoidal shape when viewed from a direction that is parallel to the first surfaces of the luminous bodies.

4. The light-emitting device according to claim 1, further comprising:
a reflector disposed in a space between a first luminous body in the plurality of luminous bodies and a second luminous body in the plurality of luminous bodies, the first and second luminous bodies being adjacent to each other, the reflector configured to reflect light emitted from both the first and second luminous bodies.

5. The light-emitting device according to claim 4, wherein the reflector has a shape which narrows with increasing distance from the resin layer.

6. The light-emitting device according to claim 1, further comprising:
a resin body disposed in a space between a first luminous body in the plurality of luminous bodies and a second luminous body in the plurality of luminous bodies, the first and second luminous bodies being adjacent to each other, the resin body including a component that scatters lights emitted from the both the first and second luminous bodies.

7. The light-emitting device according to claim 1, wherein a reflective member is disposed on a side face of each phosphor layer, the side face intersecting an upper face and a lower face of said phosphor layer, the reflective member reflecting light that is at a wavelength emitted by the luminous bodies.

8. The light-emitting device according to claim 1, further comprising:
a plurality of lens that are disposed on each of the phosphor layers.

9. The light-emitting device according to claim 1, wherein the luminous bodies in the plurality of luminous bodies are electrically connected to each other in series via the wiring.

10. The light-emitting device according to claim 1, wherein the luminous bodies in the plurality of luminous bodies are electrically connected to each other in parallel via the wiring.

11. The light-emitting device according to claim 1, wherein the first portion of the wiring extends in a direction perpendicular to the resin layer and a second portion of the wiring extends in a direction parallel to the resin layer, and the second portion is not in the resin layer.

12. A light-emitting device, comprising:
a resin layer;
a plurality of luminous bodies that are spaced from each other on the resin layer and each include:
a first semiconductor layer of a first conductivity type, the first semiconductor layer having a first surface and a second surface opposite the first surface;
a light emitting layer disposed on a portion of the first surface of the first semiconductor layer;
a second semiconductor layer disposed on the light emitting layer, the second semiconductor layer being a second conductivity type;
a plurality of first conductive portions that are in the resin layer and electrically connected to the first semiconductor layer of each luminous body at a portion of the first surface on which the light emitting layer is not disposed;
a plurality of second conductive portions that are in the resin layer and electrically connected to the second semiconductor layer of each luminous body; and
a plurality of phosphor layers that are disposed on the second surface of the first semiconductor layer of each luminous body, the phosphor layers being spaced from each other.

13. The light-emitting device according to claim 12, further comprising:
an insulating film between the resin layer and the luminous bodies, wherein the first conductive portions and the second conductive portions extend through openings in the insulating film to electrically connect to the respective first and second semiconductor layers.

14. The light-emitting device according to claim 12, wherein each phosphor layer has a tapered shape that narrows with distance from the second surface of the first semiconductor layer.

15. The light-emitting device according to claim 12, further comprising:
a reflector disposed between adjacent luminous bodies and extending into a space between adjacent phosphor layers.

16. The light-emitting device according to claim 12, further comprising:
a resin body disposed between adjacent luminous bodies and extending into a space between adjacent phosphor layers, the resin body including a component that scatters light emitted from the adjacent luminous bodies.

17. The light-emitting device according to claim 12, further comprising:
a plurality of lens that are disposed on each of the phosphor layers.

18. The light-emitting device according to claim 12, wherein a reflective member is disposed on a side face of each phosphor layer, the side face intersecting an upper face and a lower face of the phosphor layer, the reflective member reflecting light that is at a wavelength emitted by the luminous bodies.

19. A method of manufacturing a light-emitting device, the method comprising:
forming a first semiconductor layer having a first conductivity type on a substrate;
forming a light-emitting layer on the first semiconductor layer;
forming a second semiconductor layer having a second conductivity type on the light-emitting layer;
removing a first portion of the second semiconductor layer and a first portion of the light-emitting layer to expose a first portion of the first semiconductor layer;
removing a portion of the first portion of the first semiconductor layer to expose a portion of the substrate thereby forming a spacing between remaining portions of the first semiconductor layer so as to form a plurality of luminous bodies that each include a remaining portion of the first semiconductor layer, a remaining portion of the light-emitting layer, and a remaining portion of the second semiconductor layer;
forming a first electrical connector electrically connected to the first semiconductor layer in each respective luminous body;
forming a second electrical connector electrically connected to the second semiconductor layer of each respective luminous body;
forming a resin layer to cover the plurality of luminous body formed on the substrate;
removing the substrate to thereby expose a surface of the first semiconductor layer of each luminous body;
forming a phosphor layer on the surface of the first semiconductor layer of each luminous body, each phosphor layer thus formed being separated from phosphor layers of adjacent luminous bodies; and
forming a wiring that electrically connects the luminous bodies.

20. The method according to claim 19, wherein the wiring electrically connects the first electrical connector of a first luminous body in the plurality of luminous bodies to the second electrical connector of a second luminous body in the plurality of luminous bodies, the first and second luminous bodies being adjacent to each other.
